(19) United States
(12) Patent Application Publication
(10) Pub. No.: US 2023/0234014 A1
(43) Pub. Date: Jul. 27, 2023

(54) REACTOR SYSTEM WITH SOURCE VESSEL WEIGHT MONITORING

(71) Applicant: ASM IP Holding B.V., Almere (NL)

(72) Inventors: Venkata Motupalli, North Plains, OR (US); Pawan Sharma, Tempe, AZ (US); Ankit Kimtee, Phoenix, AZ (US); Eric Shero, Phoenix, AZ (US); Todd Dunn, Cave Creek, AZ (US)

(21) Appl. No.: 18/100,331

(22) Filed: Jan. 23, 2023

Related U.S. Application Data
(60) Provisional application No. 63/302,611, filed on Jan. 25, 2022.

(51) Int. Cl. B01J 19/00

(52) U.S. Cl. CPC B01J 19/004; B01J 19/0046

(57) ABSTRACT

A source vessel weight monitoring assembly for use in reactor systems to provide real-time and direct measurements of the availability of source or process materials from a source vessel. The assembly includes one or more force or load sensors, such as load cells, positioned between a bottom wall of the source vessel and a support element for the vessel (e.g., a base of a source vessel enclosure). The sensors are positioned to at least partially support the vessel, and a signal conditioning element processes the output electrical signals from the sensors, then a controller processes the output signals from the signal conditioning components with a conversion factor, for example, to determine a current weight of the source vessel and process material (e.g., solid, liquid, or gaseous precursor) stored therein. The controller uses this weight to calculate the amount of available process material or chemistry in the source vessel.

### CROSS-REFERENCE TO RELATED APPLICATIONS

This application is a nonprovisional of, and claims priority to and the benefit of, U.S. Provisional Pat. Application No. 63/302,611, filed Jan. 25, 2022 and entitled “REACTOR SYSTEM WITH SOURCE VESSEL WEIGHT MONITORING,” which is hereby incorporated by reference herein.

### FIELD OF THE DISCLOSURE

The present disclosure relates generally to semiconductor fabrication methods and systems using precursor or other process materials stored, typically at high temperatures and wide range of pressures including vacuum, in system source vessels, and, more particularly, to methods and apparatus for monitoring levels or amounts of process materials, such as precursors, reactants, and the like, in solid, liquid, or gaseous form, in source vessels.

### BACKGROUND OF THE DISCLOSURE

During a deposition process, deposition or process material, which may be delivered to a wafer for example, is stored inside a temperature- and pressure-controlled source vessel inside the reactor system or tool, and the source vessel itself may be located in an enclosure at higher temperatures and wide range of pressures (e.g., within a vacuum oven). In some cases, the source vessel is stored within a source enclosure or cabinet (which may take the form of a vacuum oven in some cases) that is fluidically connected to or in communication with a reaction or processing chamber. For example, a solid source vessel may be used to provide a precursor to a wafer on a substrate support or susceptor in a reaction chamber. During wafer processing, the precursor is consumed. When the source vessel is running out of or low on the precursor (or other processing material), the amount of vapor reaching the wafer may get affected, which can cause non-uniform deposition between wafer-to-wafer runs in the reactor system or even on a particular wafer. Such non-uniformity can lead to scrap wafers, and the batch of wafers may need to be re-run after the source vessel is refilled, which causes lower throughput.

Typical reactor systems do not provide any way to directly monitor how much chemistry is available inside a source vessel at any given time. Presently, system operators may simply wait until no or non-uniform deposition is observed to determine that a chemical source is depleted and needs refilling. In some cases, the amount of chemistry that has been used is calculated based on dose pulses after refill is performed, but errors can lead to inaccuracies in this indirect source monitoring approach. Hence, there remains a demand for a direct measurement solution for monitoring the availability of process or source materials in the source vessels of a reactor system to prevent dosage drift which may arise if precursor consumption is not monitored and falls below a certain level.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Disclosed herein, according to various embodiments, is a source vessel weight monitoring assembly for use in reactor systems to provide real-time and direct measurements of the availability of source or process materials from a source vessel. The assembly includes a plurality of sensors, such as load cells, positioned between a bottom wall of the source vessel (with a vessel support plate and a heater plate being disposed between the bottom wall and the sensors in some implementations) and a support element for the vessel (e.g., a base of a source vessel enclosure, which may take the form of a vacuum oven in some example systems). The sensors are positioned to at least partially support the vessel, and a signal conditioning element conditions the electrical signals from the load cell, and a controller processes the output signals from the signal conditioning element with a conversion factor, for example, to determine a current weight of the source vessel and process material (e.g., solid, liquid, or gaseous precursor) stored therein. The controller uses this weight to calculate the amount of available process material or chemistry in the source vessel, which can be reported to a reactor system operator to indicate a need for source refill prior to any issues with scrap or deposition non-uniformity in a reactor chamber supplied by the source vessel.

In some exemplary embodiments of the description, a reactor system is described that is adapted for monitoring source availability. The system includes a reaction chamber, a source enclosure (such as a vacuum oven), and a source vessel positioned in the source enclosure. The vessel includes an interior space adapted for receiving a volume of a source material, and the interior space is fluidically coupled to the reaction chamber. The system further includes a vessel weight monitoring assembly including a sensor assembly positioned in the source enclosure operable to sense a weight of the source vessel.

In some exemplary implementations of the system, the sensor assembly includes a plurality of force sensors, positioned between a bottom wall of the source vessel and a support element of the source enclosure, supporting at least a portion of the weight of the source vessel. The one or more force sensors each outputs an electrical signal indicative of a force applied by the source vessel on the one or more force sensors. In some cases, the force sensors include three load cells arranged in a circular pattern at 120-degree offsets, whereby the force applied to each of the three load cells is substantially equal. The system may include a vessel base heater positioned between the bottom wall of the source vessel and the support element, and the force sensors include a pneumatic load cell embedded in an outer surface of the vessel base heater.

The vessel weight monitoring assembly may further include a signal conditioning device for processing the signal of each of the one or more force sensors to calculate a weight of the source material. The processing of the signal can include amplifying the electrical signals from the load cells. The vessel weight monitoring assembly may further include a controller. The controller’s purpose or functionality is applying a conversion factor to the overall measured or gross weight of the vessel that is adapted to remove a weight of the source vessel and supporting forces applied on a lid of the source vessel by lid-attached hardware. The controller can be configured (or programmed) to generate at least one of a graphical user interface (GUI) in a display that includes imagery or text indicative of the weight or an alert based on a comparison of the weight to a refill alarm threshold. The lid-attached hardware can include at least one input line and at least one output line each including at least one of a bellow, coil gas lines, or hard gas lines to reduce the supporting forces applied to the lid. In the system, an inner space of the source enclosure has or can have an operating temperature greater than 150° C.

According to other aspects of the description, a reactor system is provided that is adapted for monitoring source availability. This system includes a source enclosure and a source vessel positioned in an inner space of the source enclosure. The source vessel includes a bottom wall, a lid, and a sidewall defining an interior space for receiving a process material. The system further includes one or more force sensors positioned within the inner space of the source enclosure to at least partially support the source vessel, and the plurality of force sensors each outputs a signal indicative of a force applied on the one or more force sensors. A signal conditioning element is provided to condition electrical signals coming from sensors. A controller is provided in the system that processes the signals output by the one or more force sensors to determine a weight of the process material.

In some embodiments of this system, the force sensors include three load cells arranged in a pattern whereby the force applied to each of the three load cells is substantially equal. In other embodiments, the system includes a vessel base heater positioned between the bottom wall of the source vessel and the support element, and the one or more force sensors comprise a pneumatic load cell embedded in an outer surface of the vessel base heater.

The processing of the signal by the controller includes applying a conversion factor to the gross measured or detected weight to account for a weight of the source vessel and supporting forces applied on a lid of the source vessel by lid-attached hardware. In some cases, the controller generates at least one of a graphical user interface (GUI) in a display that includes imagery or text indicative of the weight or an alert based on a comparison of the weight to a refill alarm threshold. In these or other example systems, the lid-attached hardware includes at least one input line and at least one output line each including at least one of a bellow and a coil to reduce the supporting forces applied to the lid.

According to further aspects of the description, a method is described of monitoring availability of source material in a reactor system. The method includes receiving at least one signal, and typically a plurality of signals, from a set of force sensors positioned between a source vessel and a support element vertically supporting the source vessel in the reactor system. The method also includes converting the at least one signal to a weight measurement and calculating a weight of source material in the source vessel based on the weight measurement. In some cases, the volume of precursor is determined using the density of the precursor, with Volume = Weight/Density. This will be helpful when dealing with a liquid because liquid density changes with temperatures and liquid volume inside the vessel can be further used to find the vapor pressure.

The calculating of the weight can include applying a conversion factor to account for a weight of the source vessel and for lifting forces applied on a lid of the source vessel by lid-attached hardware. In some implementations, the set of force sensors includes at least three load cells arranged to each receive an equal or substantially equal (e.g., within 5 percent) proportion of forces applied by the source vessel upon the set of force sensors. The method may further include generating a GUI with imagery or text indicative of the weight of the source material. Additionally, the method can include comparing the weight of the source material to a refill alarm setpoint, and, based on the comparing, generating a refill alert.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 is a functional block diagram of an exemplary reactor system of the present description with a vessel weight monitoring assembly operable to monitor source availability based on vessel weight measurements.

FIG. 2 illustrates schematically design and operation of a vessel weight monitoring assembly such as may be used in the reactor system of FIG. 1.

FIG. 3 is side perspective view of a portion of a reactor system including one exemplary implementation of a sensor assembly of a vessel weight monitoring assembly of the present description.

FIG. 4 is a schematic bottom view of the reactor system of FIG. 3 showing positioning of three load sensors of the sensor assembly relative to an outer surface of the vessel bottom support plate.

FIG. 5 provides graphical results of three calibration runs for a sensor assembly used to determine source or process material weights in a source vessel.

FIG. 6 illustrates another portion of a reactor system including another exemplary implementation of a sensor assembly at least partially embedded in a vessel base heater.

FIG. 7 is a flow diagram of an exemplary source or process material availability monitoring method that may be performed by operation of the reactor systems described in FIGS. 1-6 based on direct vessel weight measurements.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the term “chemical vapor deposition” (CVD) may refer to any process wherein a substrate is exposed to one or more volatile precursors, which react and/or decompose on a substrate surface to produce a desired deposition.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term atomic layer deposition, as used herein, is also meant to include processes designated by related terms such as, chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As described in greater detail below, various details and embodiments of the disclosure may be utilized in conjunction with processes carried out in reactor systems, e.g., semiconductor fabrication systems, to monitor an amount of a process material available for a reaction or process chamber. The “processes” may include nearly any normally carried out in such reactor systems such as deposition, etching, purging, and the like that may be performed during ALD, CVD, and other processes on a substrate (e.g., a wafer). The “process material” (or “source” or “source material”) may be provided to the reaction chamber from a source vessel where it may in solid, liquid, or gaseous form and may include precursors, reactants, and the like used during the processes performed during operations of the reactor system.

Reactor systems having direct measurement-based methods may provide the ability to monitor availability of source or process materials in source vessels. Accordingly, various embodiments of the present technology disclose a reactor system comprising a vessel weight monitoring assembly. Exemplary assemblies can be configured, as described in detail below, to directly monitor the weight of a source vessel and to, in response, update the system operator or user on the quantity of chemistry or source/process material available in the source vessel. With this information, the refill sequence for the source vessel can be planned, thereby preventing wafer wastage. In various embodiments, the source vessels may be in vessel enclosures, such as vacuum ovens, where operating temperatures are high (e.g., exceeding 150 to 200° C. or even exceeding 300° C. in some cases) and where operating pressures are low (e.g., lower than atmosphere).

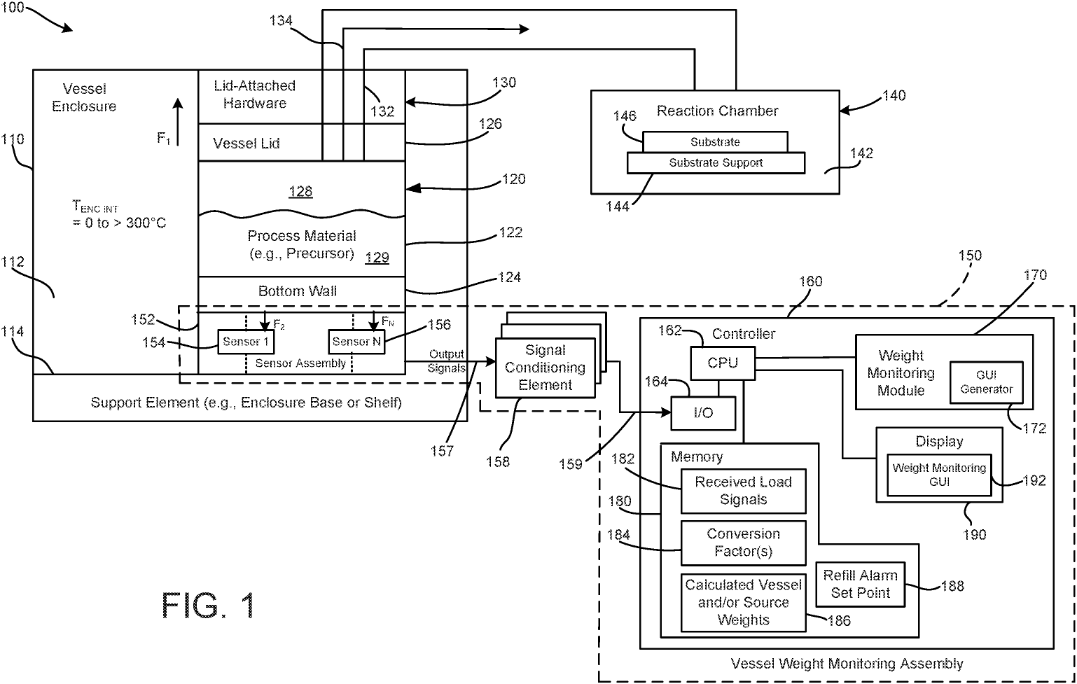

FIG. 1 is a functional block diagram of a reactor system 100 of the present description with a vessel weight monitoring assembly 150 operable to monitor source availability based on vessel weight measurements (e.g., via calculation of quantity of process or source material such as a solid precursor or the like 129 in a source vessel 120). The system 100 is shown in simplified form, but it will be understood by those skilled in the art that additional components, such as other source vessels 120, gas or material distribution systems, a system controller, and the like may be included as useful for performing ALD, CVD, or other semiconductor or fabrication processes.

As shown, the system 100 includes a vessel enclosure 110 that is used to contain the source vessel 120. The enclosure 110 may be configured, such as a vacuum oven, to heat the vessel 120 such as to temperature in the range of 150 to 300° C. or greater and maintain the interior space 112 in which the vessel 120 is placed at desired pressures, such as below atmosphere. The source vessel 120 includes an inner space 128 adapted for receiving and containing a quantity of process or source material 129, and this space 128 is defined by sidewall(s) 122, a bottom wall 124, and a vessel lid 126, which all may be formed of a metal such aluminum, a steel, or the like to facilitate efficient heat transfer to the material 129.

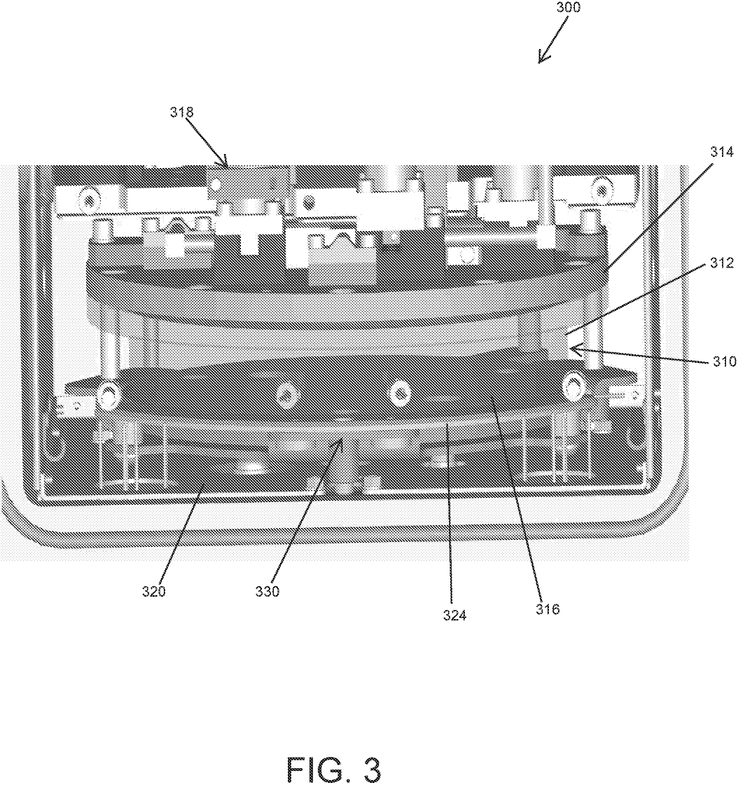

The vessel enclosure 110 includes a support element 114 for supporting (in a vertical direction) the vessel 120 within the interior space 112, and, in some embodiments, an additional support plate (not shown in FIG. 1 but shown in FIG. 3) may be disposed between the support element 114 and the lower or outer surface of the bottom wall 124 to retain the vessel 120 at a height above the support element 114 (e.g., spaced apart 10 to 30 mm or the like). The system 100 further includes a set of lid-attached hardware 130 including one or more outlet tubes or pipes 132 for fluidically coupling the space 128 with the reaction chamber inner space 142 to facilitate delivery of the process material (e.g., a precursor) 129 to the reaction chamber 140, as shown with arrow 134, during processing operations of the system 100. In this regard, the reaction chamber 140 includes a substrate support or susceptor 144 for supporting substrates (e.g., wafers) 146 within inner space 142 of the chamber 140 to be exposed to the process material 129.

In practice, the weight of vessel 120 is supported by the support element 114 of the enclosure 110 and also, to some degree, by the lid-attached hardware 130 as shown with arrow F₁. In addition to outlet piping 132, the lid-attached hardware 130 may include inlet piping, sensor lines, and the like. In some embodiments, the outlet piping 132 (and/or inlet piping) as well as other lid-attached hardware 130 may be designed to provide less vertical support of the vessel 120 such that a larger portion of the weight of the vessel 120 is supported by the support element 114 to facilitate direct measurement of the vessel weight. In brief, the hardware 130 such as line(s) 132 may be bellowed, coiled gas lines, or hard gas lines or the like to apply minimal lifting force upon the lid 126 and/or vessel 120.

To provide direct measurement and monitoring of the quantity of the process material 129 in the vessel 120, the system 100 includes the vessel weight monitoring assembly 150. The assembly 150 includes a sensor assembly 152 that is positioned, at least partially, within the inner space 112 of the enclosure 112. Particularly, the assembly includes one, two, three, or more force or load sensors 154, 156, e.g., load cells or the like, that are positioned or disposed between the bottom wall 124 of the vessel 120 (and, in some cases, a support plate attached to the bottom wall 124 as shown in FIG. 3) and the upper surface of the support element 114. The force sensors 154, 156 are positioned so as to support the full weight of the vessel 120 (and, as appropriate, weights of a heater plate and a vessel plate (not shown but included in various embodiments of a vessel enclosure 110) and source or process material 129 (as shown by arrows F₂ to F_{N}) reduced by lift or vertical upward forces applied to the vessel lid 126 by the lid-attached hardware 130. To this end, the force sensors 154, 156 are devices designed to translate applied mechanical forces, such as compressive forces, into output signals 157 whose values can be used to reflect the magnitude of the forces (or weight of vessel 120).

As shown, the signals 157 output by the force sensors 154, 156 are transmitted (in a wired or wireless manner) first to signal conditional elements 158 (with one provided for each load cell or sensor 154, 156 in most cases) to generate a conditioned signal 159 that is provided to a controller 160 of the monitoring assembly 150. The signal conditioning element(s) 158 conditions the electrical signal from each load cell or other sensor 154, 156, such as by amplifying the electrical signal from the load cell. The controller 160 may take the form of nearly any computer device and is shown to include a processor(s) 162 that manages operations of input and output (I/O) devices 164, which function to receive the signals 157 output by the sensors 154, 156. The processor 162 executes code, instructions, and/or software (which may be in memory/data storage 180) to provide the functions of a weight monitoring module 170. The processor 162 also manages memory 180 including storing and accessing the signals 157 as shown at 182.

The module 170 acts to process the received load signals 182 including applying a conversion factor(s) 180 from memory 182 to calculate the current vessel and source material weights 186. In brief, the conversion factors 184 are generated through testing and calibrating the sensors 154, 156 to convert the signals 182 indicative of the sensed forces, F₂ to F_{N}, into units of force or load, e.g., grams. The conversion factors 184, which may include algorithms, may also be used by the module 170 to determine the quantity of the material 129 by first determining the overall or gross weight of the vessel 120 and material 129 stored in the vessel 120 by adding the forces, F₁, applied by the lid-attached hardware 130 (and/or other components in the space 112 contacting the vessel 120) to the sensed forces, F₂ to F_{N}, and then subtracting the known weight of the vessel 120 when empty.

With the calculated source or process material weight 186 in hand, the module 170 can determine whether refilling is required. The module 170 may retrieve a refill alarm setpoint 188 (e.g., a minimum amount or weight of material 129 desired in the vessel 120 for further processing by system 100 such as 100 grams for some vessel designs and some particular process materials 129) and compare this with the calculated weight or quantity 186 of the material 129 currently in the vessel 120. When the source weight 186 is at or below the setpoint 188, the module 172 may provide an alarm, or other suitable indicator, to an operator of the system 100 such as via an audible alarm, a visual alarm, a digital message to a client device, and/or other messaging processes.

In this regard, the weight monitoring assembly 170 may include a graphical user interface (GUI) generator 172 that is adapted to generate and display a weight monitoring GUI 192 in a display 190 (or operator’s client device). The weight monitoring GUI 192 may include imagery and/or text messaging indicating information useful in monitoring the source or process material 129 and its availability, and this displayed information may include current quantities of the material 129 as directly measured by the assembly 150 along with the refill alarm setpoint 188 (e.g., with a display similar to an automobile speedometer or the like). The information displayed in the GUI 192 may also include an indicator that the calculated source quantity 186 is below or at the setpoint 188 (or has not yet met the setpoint 188) such as with a red light when refilling is indicated and a green light when refilling is not indicated (and, in some cases, a yellow light when refilling will be desirable soon).

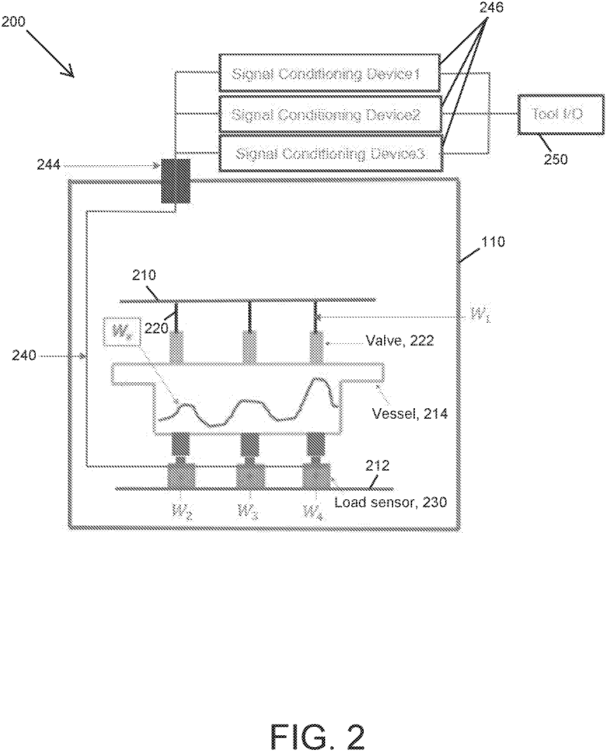

FIG. 2 illustrates schematically the design and operation of a vessel weight monitoring assembly 200 such as may be used as assembly 150 in the reactor system 100 of FIG. 1. The assembly 200 includes three load sensors 230 positioned between a bottom wall of a vessel 214 and a support element 212 (e.g., a bottom wall of a source enclosure). The assembly 200 further includes bellowed, coiled gas lines, or hard gas lines or the like 220 (input/output lines making up part of lid-attached hardware) for inputting material during refill or outputting material during wafer/substrate processing via valves 222 coupled to a lid of the vessel 214. The bellowed lines 220 are each shown to be coupled at a lower end to one of the valves 222 (and lid of vessel 214) and at an upper end to an upper support element 210 (e.g., a top wall of the source enclosure). The lines 220 apply a lifting or upward supporting force, W₁, on the vessel 214, which is reduced in magnitude by the use of bellows (or coils/loops) in lines 220 when compared to rigid conventional lines (which are typically hard plumbed) found in many reactor systems and such reduction is desirable for increasing the accuracy of the weight measurement of the vessel 214 via load sensors 230.

The assembly 200 is useful for directly monitoring changes in gross weight of a source (e.g., a precursor) vessel 214 using the load sensors 230 as the weight changes during source (e.g., precursor such as HFCl₄ or the like) consumption. The load sensors 230 may be placed under the vessel 214 (its bottom wall) or a support plate or frame holding the vessel 214 within an enclosure (e.g., a vacuum oven or the like). Electrical wire(s) 240, e.g., electrical wire compatible with high temperatures within vessel enclosure 110, is used to communicatively link each sensor 230 with a signal condition device or element 246 via a vacuum electrical feedthrough 244 (e.g., feedthrough compatible with high temperatures in enclosure 110) in the enclosure 110 or its wall. The signal conditioning devices 246 condition the electrical signals from each load sensor 230 as discussed above (such as by applying a conversion factor) prior to the conditioned signals being provided to the tool I/O 250 (such as I/O 164 in FIG. 1 for controller 162).

Weight is proportionally divided across supports as shown by the arrows, W₁ to W₄, with W₁ representing loads carried by lines 220 (and/or other hardware in the enclosure) and with W₂, W₃, and W₄ representing loads carried by and sensed by load sensors 230. The total load is equal to the vessel weight plus the weight of the precursor/source, Wₓ, in the vessel 214, and changes in the sum of weights (or sensed loads) W₂, W₃, and W₄ are proportional to changes in the source or process material weight such that a conversion factor (e.g., a numerical model to correlate change in precursor weight to change in this sum of sensed forces/loads) can be determined via testing and calibration and then applied to measure values for these forces/loads to calculate the weight of the source or process material within the vessel 214.

FIG. 3 is side perspective view of a portion of a reactor system 300 including one exemplary implementation of a sensor assembly of a vessel weight monitoring assembly of the present description. As shown, a source vessel 310 is provided within an interior space of an enclosure (e.g., a vacuum oven) that includes a support element or bottom 320 upon which the vessel 310 is vertically supported. The vessel 310 includes a sidewall 312, a lid or top wall 314 and a bottom wall 316, which together define an inner space configured or adapted to receive a quantity of source or process material (e.g., a precursor or the like). The system 300 also includes hardware 318 attached to the lid 314, and this hardware 318 applies some upward forces upon the vessel 310 such that the entire weight of the vessel 310 is not borne by the support element 320 (and needs to be accounted for in source weight calculations as discussed above with reference to FIG. 2).

The vessel 310 in the illustrated embodiment of FIG. 3 is mounted upon a support plate or frame 324 in the enclosure, and the sensor assembly includes three force sensors in the form of load cells. One of these load cells 330 is in view in FIG. 3 and is shown to be positioned or disposed between the bottom wall 316 of the vessel 310 and the upper surface of the enclosure support element 320. More particularly, the load cell 330 is affixed or mounted to a bottom surface of support plate or frame 324, which is abutting the bottom wall 316 of the vessel 310. With this arrangement, all of the weight of the vessel 310 is supported by the load sensors including the load cell 330 except for that borne by the lid-attached hardware 318. In some cases, the pneumatic lines are coiled or bellowed to try to ensure the vessel is floating or nearly floating upon the load cells 330. Additional design aspects may include ensuring the heater cable (which may be part of hardware 318 but not shown in detail in FIG. 3) is flexible and that the valve plate (which may be part of hardware 318 in some case but is not shown in detail in FIG. 3) is not supported by the vessel 310.

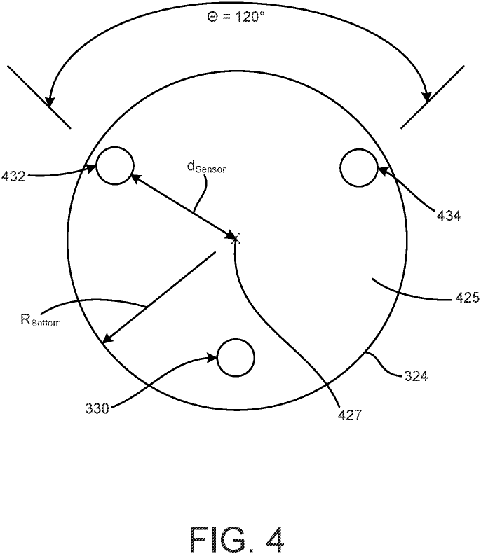

FIG. 4 is a schematic bottom view of the reactor system 300 of FIG. 3 showing positioning of three load sensors 330, 432, 434 of the sensor assembly relative to an outer surface 425 of the vessel bottom support plate or frame 324. One, two, or four or more load cells may be used to implement the sensor assembly, with three being useful in some implementations as this number can readily be arranged in a circular pattern to equally or substantially equally balance the loads (e.g., equal portion of vessel and source weight is applied to each load sensor 330, 432, 434). As shown, the load sensors 330, 432, 434 are arranged equidistally from the plate center 427, with dₛₑₙₛₒᵣ being equal for all three and being relatively close to the size of the plate radius, R_{Bottom}, so that the sensors 330, 432, 434 are near the peripheral or outer edges of the plate 324. The sensors 330, 432, 434 are positioned about the outer edge of the plate 324 in a circular pattern so as to be radially separated by matching angles, θ, of 120 degrees.

A variety of sensors may be used for the sensors 330, 432, 434. In some cases, the vertical spacing may limit the choice of sensor, with one exemplary implementation requiring that the overall vertical height of each sensor (which may be the sensor thickness plus a height of a sensor mounting fastener used to mount the sensor to the support element or bottom of the enclosure) be about 15 mm. The sensor may also be able to be used in higher temperature applications such as temperatures greater than 200° C., 250° C., or 300° C., and the operating range of the sensor should meet or exceed expected use temperatures. In various embodiments, the system may integrate any suitable load sensors or cells such as a 30 N load sensor with an operating range of 200° C., a 100 N load sensor with an operating range of 200° C., or the like. Modifications to communication lines from such sensors may be desired to suit a particular application such as an environment inside a vacuum oven.

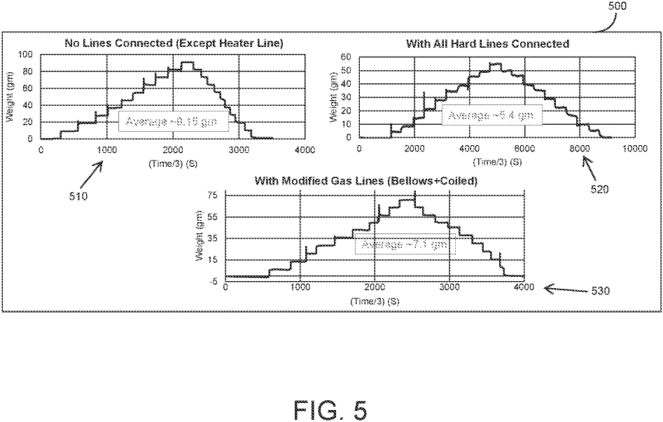

FIG. 5 provides graphical results 500 of three calibration runs for a sensor assembly with three load sensors (as shown in FIGS. 3 and 4) used to determine source or process material weights in a source vessel. Graph 510 shows results of a calibration run with no lines connected to the vessel except a heater line, graph 520 shows results of a calibration run with all hard lines (e.g., lid-attached hardware) connected to the vessel lid, and graph 530 shows results of a calibration run with modified gas lines (bellows combined with coils) connected to the vessel lid. Testing involved loading and unloading of known amounts of weight, with the vessel weight zeroed to provide a measurement of the precursor/process material. Load sensor repeatability and accuracy were shown to be acceptable, with the heater line not affecting results. Using flexible input and output lines was desirable for providing the reading closer to that of the process material.

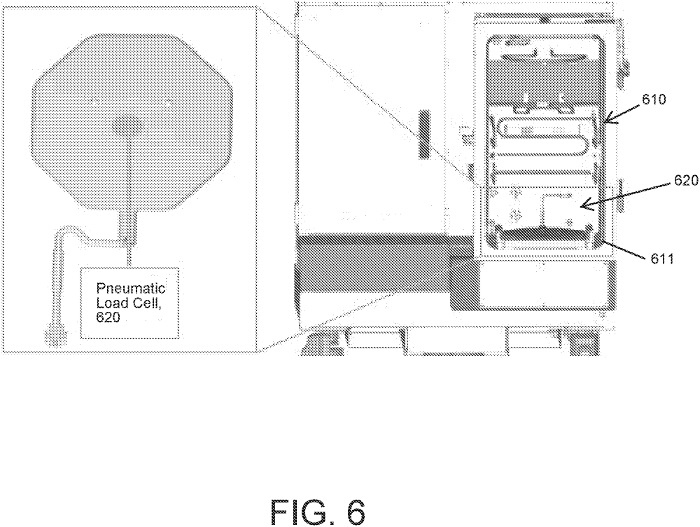

FIG. 6 illustrates another portion of a reactor system including another exemplary implementation of a sensor assembly at least partially embedded in a vessel base heater. Particularly, a vessel base heater 610 is illustrates that has been modified to include a load cell 620 inside the heater surface 611. The force sensor 620 may be chosen to be capable of withstanding high temperatures, such as 300° C. or greater.

A single load sensor 620 is shown that may take the form of a pneumatic or pan-style load cell. Particularly, the sensor 620 may include a source of pressurized air or gas that is fed through a pressure regulator to a chamber inside the load cell. A flexible diaphragm is compressed when a compressive force (e.g., the weight of the vessel containing source or process material) is applied to the top surface of the load cell. A pressure gauge measures the pneumatic pressure result from the weight/compressive force being applied, and the amount of pressure needed to balance out the weight of the object being measured can be used to measure the weight. The sensed pressure is converted to an electrical signal communicated to a controller (as discussed with reference to FIG. 1) for conversion into a weight and for use in calculating the current weight of the material in the vessel supported by the base heater 610.

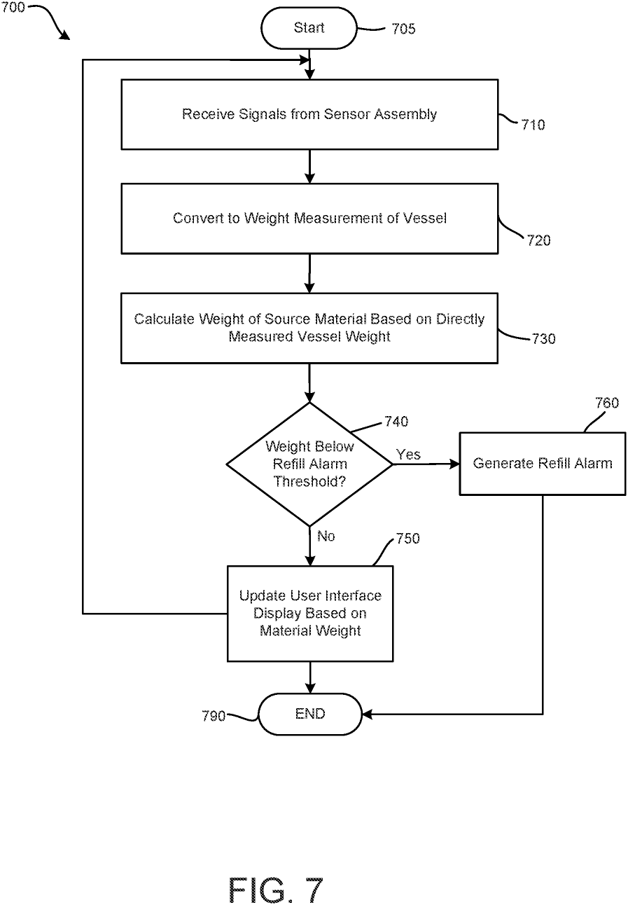

FIG. 7 is a flow diagram of an exemplary source or process material availability monitoring method 700 that may be performed by operation of the reactor systems described in FIGS. 1-6 based on direct vessel weight measurements. The method 700 starts at 705 such as with installing a vessel weight monitoring assembly (such as the assembly 150 of FIG. 1) in a reactor system including providing a sensor assembly within a source vessel enclosure. The method 700 then continues at 710 with receiving output signals from the one or more sensors of the sensor assembly operating to sense changes in the weight of a source vessel. At step 720, the electrical signals from the sensors are converted, such as by a controller or by a conversion module/device, to a weight (or force) measured for the source vessel that contains a volume of source or process material. The method 700 continues at 730 with the controller using a weight monitoring module to calculate the current weight (or quantity) of source or process material in the source vessel based on the vessel weight of step 720.

At step 740, a determination is made (e.g., by a monitoring assembly controller) as to whether the weight calculated in step 730 is at or below the refill alarm threshold (e.g., is weight of material at or below 100 grams or the like). If not, the method 700 may continue at step 750 with updating the user interface displayed to a system operator on a display device (e.g., a computer monitor, a client device display, or the like) to reflect the current material weight. The method 700 may then continue at 710 with receiving additional signals from the sensor assembly. If at 740 the material weight is determined to be at or below the threshold, the method 700 may continue at 760 with the controller generating a refill alert or alarm, which may involve providing a red indicator light in a user interface of the operator’s display, may involve providing an audible alarm, and/or may involve generating and transmitting an alert message to the operator (e.g., sending an e-mail, a text message, or the like to an operator client device). The method 700 may then end at 790 such as until after the vessel has been refilled.

In various embodiments of the description, the force sensors may be implemented using a compact, stainless steel, single point, strain gauge-based load cell, which may have a range of 0 to 100N. The load cell may be mounted under a precursor vessel for enabling real-time weight direct measurement of precursor and vessel. In some cases, three load sensors are mounted right under the vessel holding plate and situated equally at 120-degrees angles. Then, in operations, the total weight measured will be the sum of all three load sensors readings. The load cell weight measurement response is linear after each vessel change.

In practice, hard gas lines affect the actual weight measurement of the load cell by a constant factor. The constant factor depends on the line stiffness. The constant factor does not typically change as long as the vessel and gas lines are not physically contacted or modified. Generally, the load cell reading is not affected by the vacuum in the steady state. The load cell chosen to act as the force sensor is compatible with a high-temperature environment such as one with temperatures up to 225° C., with wire material often being a design limitation.

Operations of the weight monitoring assembly include receiving electrical signals from the load cells and using signal condition divide for each load cell to condition the electrical signals coming from each load cell. A processor performing an algorithm(s) then converts the conditioned signal to a weight value using a calibration factor generated for each load cell. Then, the weight value measured by load cells is then compared to the predefined threshold value for the vessel. Next, an alarm is generated if the weight is below the threshold; otherwise, the display and user interface is updated based on the measured weight.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Reference throughout this specification to features, advantages, or similar language does not imply that all of the features and advantages that may be realized with the present disclosure should be or are in any single embodiment of the invention. Rather, language referring to the features and advantages is understood to mean that a specific feature, advantage, or characteristic described in connection with an embodiment is included in at least one embodiment of the subject matter disclosed herein. Thus, discussion of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112(f) unless the element is expressly recited using the phrase “means for.”

The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of”, when used with a list of items, means different combinations of one or more of the listed items may be used and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Any reference to attached, fixed, connected or the like may include permanent, removable, temporary, partial, full and/or any other possible attachment option. Additionally, any reference to without contact (or similar phrases) may also include reduced contact or minimal contact. In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A reactor system, comprising:
a reaction chamber;
a source enclosure;
a source vessel positioned in the source enclosure, the source vessel comprising an interior space adapted for receiving a volume of a source material, wherein the interior space is coupled to the reaction chamber; and
a vessel weight monitoring assembly comprising a sensor assembly positioned between a bottom wall of the source vessel and a support element of the source enclosure, wherein the source assembly comprises a plurality of force sensors configured to sense a combined weight of the source vessel and the source material.

2. The reactor system of claim 1, wherein each of the force sensors is configured to output a signal indicative of a force applied by the source vessel on the one or more force sensors.

3. The reactor system of claim 1, wherein each of the force sensors comprises a load cell and the load cells are arranged in a circular pattern at 120-degree offsets.

4. The reactor system of claim 1, further comprising a vessel base heater positioned between the bottom wall of the source vessel and the support element, wherein the one or more force sensors comprise a pneumatic load cell embedded in an outer surface of the vessel base heater.

5. The reactor system of claim 2, wherein the vessel weight monitoring assembly further comprises a controller configured to process the signal of each of the plurality of force sensors and calculate a weight of the source material according to the processed signals.

6. The reactor system of claim 5, wherein processing the signal comprises applying a conversion factor to the combined weight to remove a weight of the source vessel and forces applied on a lid of the source vessel by lid-attached hardware.

7. The reactor system of claim 5, wherein the controller generates an indicator indicative of the weight based on a comparison of the calculated weight of the source material to a minimum threshold.

8. The reactor system of claim 5, wherein the lid-attached hardware comprises an input line and an output line and wherein each of the input line and output line comprises a bellow or a coil.

9. The reactor system of claim 8, wherein the bellow or the coil is positioned between the lid of the source vessel and an upper wall of the source enclosure.

10. The reactor system of claim 2, wherein an inner space of the source enclosure has an operating temperature greater than 150° C.

11. A reactor system adapted for monitoring source availability, comprising:
a source enclosure;
a source vessel positioned in an inner space of the source enclosure, wherein the source vessel comprises a bottom wall, a lid, and a sidewall defining an interior space for receiving a source material;
a plurality of force sensors positioned adjacent to and in contact with the bottom wall of the source vessel, wherein each of the plurality of force sensors is configured to output a signal indicative of a force applied on the respective one of the plurality of force sensors;
a signal conditioning element for each of the plurality of force sensors adapted to condition the signal output by each of the plurality of force sensors; and
a controller configured to process the signal output by the signal conditioning elements to compute a weight of the source material.

12. The reactor system of claim 11, wherein each of the plurality of force sensors comprises a load cell and the load cells are arranged equidistant from each other.

13. The reactor system of claim 11, further comprising a vessel base heater positioned between the bottom wall of the source vessel and the support element, wherein each of the plurality of force sensors comprises a pneumatic load cell embedded in an outer surface of the vessel base heater.

14. The reactor system of claim 11, wherein the processing of the signal includes applying a conversion factor to a combined weight of the source vessel and the source material to account for a weight of the source vessel and forces applied on a lid of the source vessel by lid-attached hardware.

15. The reactor system of claim 11, wherein the controller generates an indicator indicative of a current weight of the source material based on a comparison of the computed weight of the source material to a refill alarm threshold.

16. The reactor system of claim 14, wherein the lid-attached hardware comprises an input line and an output line and wherein each of the input line and output line comprise a bellow or a coil.

17. A method of monitoring availability of source material in a reactor system, comprising:
receiving a plurality of signals from a set of force sensors positioned between a source vessel and a support element vertically supporting the source vessel in the reactor system;
converting the at least one signal to a weight measurement; and
calculating a weight of source material in the source vessel based on the weight measurement.

18. The method of claim 17, wherein the calculating of the weight of the source material comprises applying a conversion factor to a computed combined weight of the source vessel and the source material to account for a weight of the source vessel and for forces applied on a lid of the source vessel by lid-attached hardware.

19. The method of claim 17, wherein the set of force sensors includes at least three load cells arranged to each receive an equal proportion of forces applied by the source vessel upon the set of force sensors.

20. The method of claim 17, further comprising generating an indicator indicative of the weight of the source material; comparing the calculated weight of the source material to a minimum threshold value; and generating a refill alert based on the comparison.
